(19) United States
(12) Patent Application Publication
(10) Pub. No.: US 2025/0210556 A1
(43) Pub. Date: Jun. 26, 2025

(54) SEMICONDUCTOR PACKAGE

(71) Applicant: Samsung Electronics Co., Ltd., Suwon-si (KR)

(72) Inventor: KEUMHEE MA, Suwon-si (KR)

(21) Appl. No.: 18/776,531

(22) Filed: Jul. 18, 2024

(30) Foreign Application Priority Data
Dec. 22, 2023 (KR) 10-2023-0189376

(51) Int. Cl. H01L 23/00; H01L 23/36; H01L 23/48; H01L 25/065; H10B 80/00

(52) U.S. Cl. CPC H01L 24/06; H01L 23/36; H01L 24/16; H01L 24/32; H01L 24/73; H01L 25/0657; H01L 23/481; H01L 2224/06519; H01L 2224/16146; H01L 2224/32145; H01L 2224/73204; H01L 2225/06513; H10B 80/00

(57) ABSTRACT

A semiconductor package may include a first semiconductor chip including a substrate having opposing front and back surfaces, through-vias extending from the front surface toward the back surface, dummy patterns arranged around the through-vias and such that a surface of each of the dummy patterns is exposed to the back surface, a plurality of first back pads arranged on the through-vias, and a plurality of second back pads arranged on the surface of each of the dummy patterns. A second semiconductor chip may be on the first semiconductor chip, and may include a plurality of first front pads and a plurality of second front pads. In a plan view, at least one of the dummy patterns overlaps two or more second back pads arranged in at least one direction of a first direction and a second direction.

### CROSS-REFERENCE TO RELATED APPLICATION(S)

This application claims the benefit under 35 U.S.C. § 119(a) of Korean Patent Application No. 10-2023-0189376 filed on Dec. 22, 2023, in the Korean Intellectual Property Office, and the entire contents of the above-identified application are incorporated by reference herein for all purposes.

### BACKGROUND

The present inventive concept relates to semiconductor packages.

Semiconductor packages installed in electronic devices require increasingly higher performance and increasingly larger capacity as well as miniaturization. To this end, semiconductor packages in which semiconductor chips including through silicon vias (TSVs) are stacked vertically are being researched and developed.

### SUMMARY

Some embodiments of the present disclosure provide semiconductor packages having improved heat dissipation characteristics.

According to some embodiments, a semiconductor package may include: a first semiconductor chip including a substrate having a front surface and a back surface, opposing each other, through-vias that extend from the front surface toward the back surface, dummy patterns arranged around the through-vias and such that that at least one surface of each of the dummy patterns is exposed to the back surface, a plurality of first back pads arranged on the through-vias, and a plurality of second back pads arranged on a first surface of the at least one surface of each of the dummy patterns exposed to the back surface; and a second semiconductor chip on the first semiconductor chip, and including a plurality of first front pads connected to the plurality of first back pads, and a plurality of second front pads connected to each of the plurality of second back pads, wherein, when viewed in a plan view, the plurality of second back pads are arranged in a first direction and a second direction, perpendicular to the first direction, and when viewed in the plan view, at least one of the dummy patterns overlaps two or more second back pads arranged in at least one direction of the first direction and the second direction among the plurality of second back pads.

According to some embodiments, a semiconductor package may include: a first semiconductor chip including a substrate having a front surface and a back surface that oppose each other, a through-via that extends from the front surface toward the back surface, a dummy pattern spaced apart from the through-via, and within a cavity recessed from the back surface toward the front surface, a back protective layer between the substrate and the dummy pattern, a first back pad on the through-via, and a plurality of second back pads disposed on the dummy pattern; and a second semiconductor chip on the first semiconductor chip, and including a first front pad connected to the first back pad, and a plurality of second front pads connected to each of the plurality of second back pads, wherein the first back pad includes a first barrier layer that is in contact with an upper surface of the through-via, and a first conductor layer on the first barrier layer, and the plurality of second back pads include a second barrier layer in contact with an upper surface of the dummy pattern, and a second conductor layer on the second barrier layer.

According to some embodiments, a semiconductor package may include: a first semiconductor chip including a substrate having a front surface and a back surface that oppose each other, a through-via that extends from the front surface toward the back surface, a first back pad on the through-via, a first protective layer between the substrate and the first back pad, and surrounding at least a portion of the through-via, a dummy pattern within a cavity that penetrates the first protective layer, a second protective layer on an inner surface of the cavity and the dummy pattern, and a plurality of second back pads on the dummy pattern; a second semiconductor chip on the first semiconductor chip, and including a first front pad connected to the first back pad, and a plurality of second front pads respectively connected to the plurality of second back pads; a plurality of connection bumps electrically connecting the first back pad and the first front pad, and the plurality of second back pads and the plurality of second front pads; and an adhesive layer between the first semiconductor chip and the second semiconductor chip, and covering at least a portion of each of the plurality of connection bumps.

### BRIEF DESCRIPTION OF THE DRAWINGS

The above and other aspects, features, and advantages of the present inventive concept will be more clearly understood from the following detailed description, taken in conjunction with the accompanying drawings, in which:

FIG. 1A is a cross-sectional view of a semiconductor package 10A according to some embodiments, FIG. 1B is a partially enlarged view of area ‘A’ of FIG. 1A, FIG. 1C is a bottom view of the upper semiconductor chip of FIG. 1A, and FIG. 1D is a plan view of the lower semiconductor chip of FIG. 1A;

FIG. 2A is a partially enlarged view of a semiconductor package according to some embodiments, FIG. 2B is a bottom view of the upper semiconductor chip of FIG. 2A, and FIG. 2C is a plan view of the lower semiconductor chip of FIG. 2A;

FIGS. 3A to 3F are diagrams for explaining a manufacturing method of the semiconductor package of FIG. 1A;

FIG. 4A is a cross-sectional view of a semiconductor package according to some embodiments, FIG. 4B is a partial enlarged view of area ‘B’ of FIG. 4A, FIG. 4C is a diagram for explaining an example of a modification, and FIG. 4D is a plan view of the lower semiconductor chip of FIG. 4A;

FIGS. 5A to 5D are diagrams for explaining a manufacturing method of the semiconductor package of FIG. 4A;

FIG. 6 is a cross-sectional view of a semiconductor package according to some embodiments;

FIG. 7 is a cross-sectional view of a semiconductor package according to some embodiments; and

FIG. 8A is a plan view of a semiconductor package according to some embodiments, and FIG. 8B is a cross-sectional view taken along line I-I′ of FIG. 8A.

### DETAILED DESCRIPTION

Hereinafter, with reference to the accompanying drawings, some examples of embodiments of the present inventive concept will be described as follows. Unless otherwise specified, in this specification, terms such as ‘upper,’ ‘upper surface,’ ‘lower,’ ‘lower surface,’ ‘side’ and the like are based on the drawings, and actually, may vary depending on the direction in which the components are disposed.

Additionally, ordinal numbers such as “first,” “second,” “third,” or the like may be used as labels for specific elements, step portions, directions, or the like to distinguish various elements, step portions, directions, or the like from each other. Terms that are not described using “first,” “second,” or the like in the specification may still be referred to as “first” or “second” in the claims. Additionally, terms referenced by a specific ordinal number (for example, “first” in a particular claim) may be described elsewhere with a different ordinal number (for example, “second” in the specification or another claim).

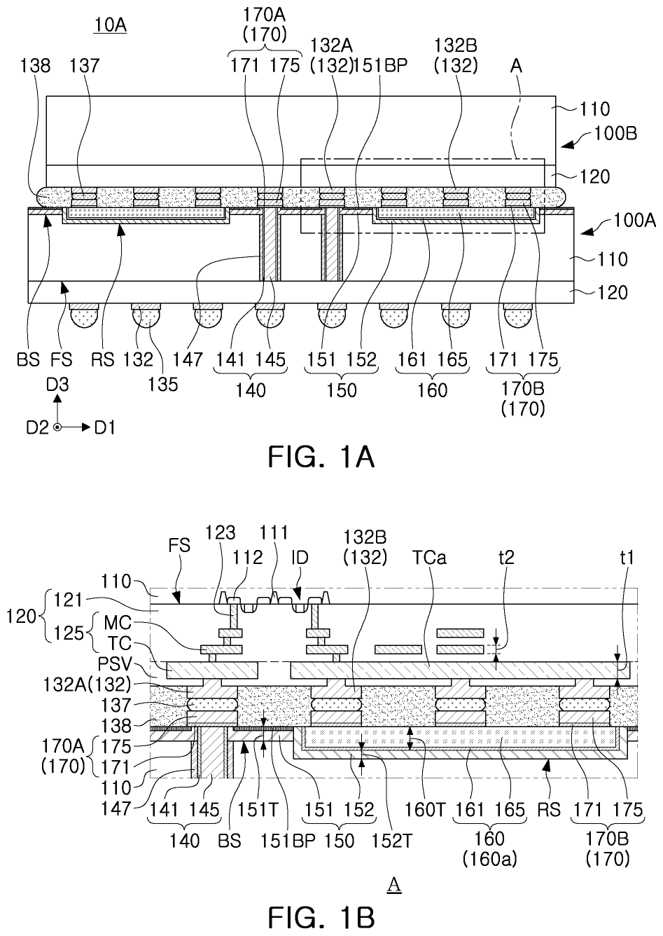

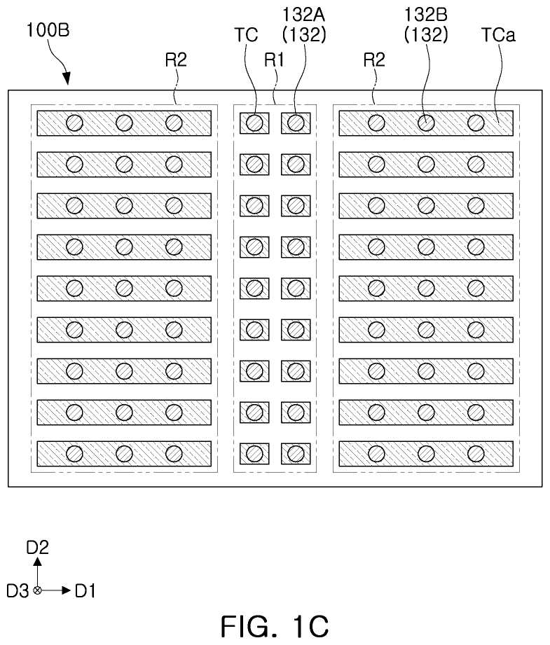

FIG. 1A is a cross-sectional view of a semiconductor package 10A according to some embodiments, FIG. 1B is a partially enlarged view of area ‘A’ of FIG. 1A, FIG. 1C is a bottom view of the upper semiconductor chip of FIG. 1A, and FIG. 1D is a plan view of the lower semiconductor chip of FIG. 1A.

Referring to FIGS. 1A to 1D, the semiconductor package 10A according to some embodiments may include two or more semiconductor chips, stacked in a vertical direction D3, for example, a first semiconductor chip 100A and a second semiconductor chip 100B.

The first semiconductor chip 100A and the second semiconductor chip 100B may include chiplets constituting a multi-chip module (MCM). The number of second semiconductor chips 100B stacked vertically or horizontally on the first semiconductor chip 100A may be two or more. The first semiconductor chip 100A may be, for example, a logic chip such as a central processor (CPU), a graphics processor (GPU), a field programmable gate array (FPGA), an application processor (AP), a digital signal processor, a cryptographic processor, a microprocessor, a microcontroller, an analog-to-digital converter, an application-specific IC (ASIC), or the like, and a memory chip including a volatile memory such as a dynamic RAM (DRAM), a static RAM (SRAM), or the like, and/or a non-volatile memory such as a phase change RAM (PRAM), a magnetic RAM (MRAM), a resistive RAM (RRAM), a flash memory device, or the like.

In FIG. 1A, a width of the first semiconductor chip 100A in a horizontal direction (e.g., D1 direction) is shown to be larger than a width of the second semiconductor chip 100B. However, in some embodiments, the width of the first semiconductor chip 100A in the horizontal direction (e.g., D1 direction) may be substantially the same as or smaller than the width of the second semiconductor chip 100B.

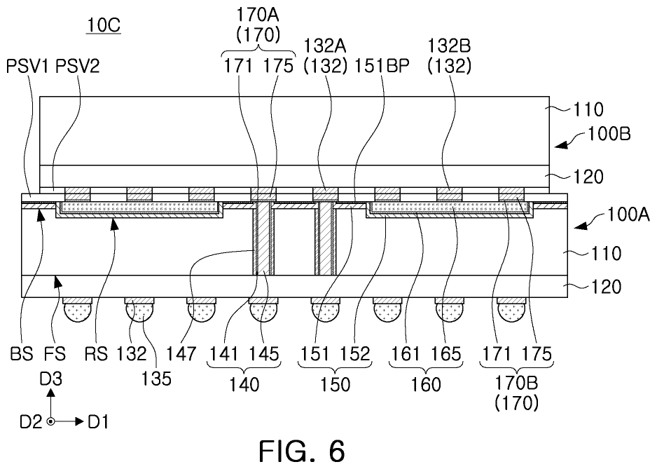

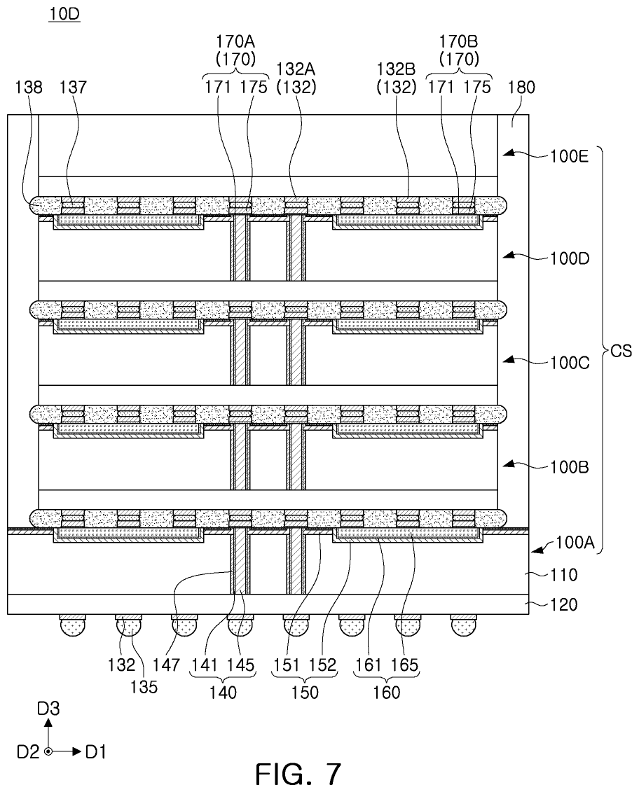

The semiconductor package 10A may further include a plurality of connection bumps 137 and an adhesive layer 138 between the first semiconductor chip 100A and the second semiconductor chip 100B, but the present disclosure is not limited thereto. Depending on the embodiment, the first semiconductor chip 100A and the second semiconductor chip 100B may be bonded and coupled to each other by inter-metal bonding and inter-dielectric bonding (see FIG. 6). In some embodiments, the semiconductor package 10A may further include a mold layer sealing at least a portion of each of the first semiconductor chip 100A and the second semiconductor chip 100B (see the embodiment in FIG. 7).

The plurality of connection bumps 137 may be between the plurality of semiconductor chips 100A and 100B. The plurality of connection bumps 137 may electrically connect the plurality of back pads 170 and the plurality of front pads 132, adjacent to each other in a vertical direction. For example, the plurality of connection bumps 137 may electrically connect a plurality of first front pads 132A and a plurality of first back pads 170A, corresponding to each other, and a plurality of first front pads 132B and a plurality of second back pads 170B, corresponding to each other. The plurality of connection bumps 137 may include, for example, tin (Sn), indium (In), bismuth (Bi), antimony (Sb), copper (Cu), silver (Ag), zinc (Zn), lead (Pb) and/or alloys thereof. In some embodiments, the plurality of connection bumps 137 may have a form in which a conductive pillar and a solder ball are combined.

The adhesive layer 138 may cover at least a portion of each of the plurality of connection bumps 137 between the plurality of semiconductor chips 100A and 100B. The adhesive layer 138 may secure a plurality of semiconductor chips 100A and 100B, vertically stacked. The adhesive layer 138 may be a non-conductive film (NCF) or a molded underfill (MUF), but the present disclosure is not limited thereto.

According to some embodiments, by introducing a large-area dummy pattern 160 connected to two or more back pads on a back surface of the first semiconductor chip 100A, a heat dissipation path in a vertical direction D3 may be secured, and heat dissipation characteristics of the semiconductor package 10A can be improved.

Hereinafter, components of the semiconductor package 10A according to some embodiments will be described in greater detail.

The plurality of semiconductor chips 100A and 100B may include a substrate 110, a front circuit layer 120, a plurality of front pads 132, a plurality of through-vias 140, a back protective layer 150, a plurality of dummy patterns 160, and/or a plurality of back pads 170. For example, the first semiconductor chip 100A may include a substrate 110, a front circuit layer 120, a plurality of front pads 132, a plurality of front through-vias 140, a back protective layer 150, a plurality of dummy patterns 160, and a plurality of back pads 170. The second semiconductor chip 100B may include a substrate 110, a front circuit layer 120, and a plurality of front pads 132.

Each substrate 110 may be a semiconductor wafer substrate having a front surface FS and a back surface BS opposing each other. For example, the substrate 110 may be a semiconductor wafer including a semiconductor element such as silicon, germanium, or silicon carbide (SiC), or a compound semiconductor such as gallium arsenide (GaAs), indium arsenide (InAs), and indium phosphide (InP). The substrate 110 may include a conductive region 112 and an isolation region 111 formed on the front surface FS. The conductive region 112 may be, for example, a well doped with impurities or a structure doped with impurities. The isolation region 111 is a device isolation structure having a shallow trench isolation (STI) structure, and may include silicon oxide.

The front circuit layer 120 may include individual devices ID, an interlayer insulating layer 121, and an interconnection structure 125. The individual devices ID may be on the front surface FS of the substrate 110. The individual devices (IDs) may include FET such as planar FET, FinFET, or the like, a flash memory, a memory device such as flash memory, DRAM, SRAM, EEPROM, PRAM, MRAM, FeRAM, and RRAM, a logic element such as AND, OR, and NOT, and various active and/or passive devices such as LSI, CIS, and MEMS.

The interlayer insulating layer 121 may be formed to cover the individual devices ID and the interconnection structure 125, to isolate electrically the individual devices ID on the substrate 110. The interlayer insulating layer 121 may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof. At least a portion of the interlayer insulating layer 121 surrounding the interconnection structure 125 may be composed of a low dielectric layer. The interlayer insulating layer 121 may be formed using a chemical vapor deposition (CVD) process, a flowable CVD process, or a spin coating process.

The interconnection structure 125 may be electrically connected to the conductive region 112 and/or the individual devices ID by an interconnection portion 123 (e.g., a contact plug). The interconnection structure 125 may be formed of a multilayer structure including, for example, aluminum (Al), gold (Au), cobalt (Co), copper (Cu), nickel (Ni), lead (Pb), tantalum (Ta), tellurium (Te), titanium (Ti), tungsten (W), or a combination thereof and vias. In some embodiments, a barrier film (not shown) including titanium (Ti), titanium nitride (TiN), tantalum (Ta), or tantalum nitride (TaN) may be between the interconnection structure 125 and the interlayer insulating layer 121.

The interconnection structure 125 may include middle conductors MC and top conductors TC. The top conductors TC may be interconnections that are most adjacent to (or closest to) the plurality of front pads 132 in a vertical direction D3. Hereinafter, the top conductors TC may be referred to as ‘connection conductors’. The middle conductors MC may be within the interlayer insulating layer 121. The middle conductors MC may be located between the front surface FS of the substrate 110 and the top conductors TC in the vertical direction D3. The top conductors TC may be positioned between the middle conductors MC and the plurality of front pads 132 in the vertical direction D3. A thickness t1 of the top conductors TC in the vertical direction D3 may be greater than a thickness t2 of the middle conductors MC in the vertical direction D3. The thickness t1 of the top conductors TC may be about 1 μm or more, for example, about 1 μm to about 30 μm, about 1 μm to about 20 μm, about 1 μm to about 10 μm, about 1 μm to 5 μm, or the like, but the present inventive concept is not limited thereto. The top conductors TC may include aluminum (Al) or an alloy thereof, but the present inventive concept is not limited thereto. In some embodiments, the top conductors TC may include a material similar to the middle conductors MC, for example, copper (Cu) or an alloy thereof.

The plurality of front pads 132 may be on the front circuit layer 120, and may be electrically connected to the interconnection structure 125. The plurality of front pads 132 may be electrically connected to the plurality of back pads 170 adjacent to each other in the vertical direction D3. The plurality of front pads 132 may include a plurality of first front pads 132A connected to the plurality of first back pads 170A, and a plurality of second front pads 132B connected to each of the plurality of second back pads 170B. The plurality of front pads 132 are made of a conductive material, such as aluminum (Al), gold (Au), cobalt (Co), copper (Cu), nickel (Ni), lead (Pb), tantalum (Ta), tellurium (Te), titanium (Ti), tungsten (W), or a combination of two or more thereof.

The plurality of front pads 132 may be on a passivation layer PSV that covers at least a portion of each of the top conductors TC. The plurality of front pads 132 may penetrate the passivation layer PSV and may be be electrically connected to the top conductors TC. In some embodiments, a barrier layer (e.g., similar to the barrier layer ‘171’ of the plurality of back pads 170, discussed in greater detail below) containing titanium (Ti), titanium nitride (TiN), tantalum (Ta), tantalum nitride (TaN) may be between at least one surface of the plurality of front pads 132, for example, between the passivation layer PSV and the plurality of front pads 132.

External connection bumps 135 may be on the front pads 132 of the lowermost semiconductor chip (e.g., the first semiconductor chip 100A) among the plurality of semiconductor chips 100A and 100B. The external connection bumps 135 may be, for example, conductive bump structures such as solder balls or copper (Cu) posts.

The plurality of through-vias 140 may extend from the front surface FS to the back surface BS of the substrate 110, and may be electrically connected to at least a portion of the plurality of front pads 132 (referred to as ‘first front pad 132A’). The plurality of through vias 140 may be connected to a signal wiring, a power wiring, and a ground wiring of the line structure 125. The plurality of through-vias 140 may be in direct contact with the first front pads 132A. A maximum width of each of the plurality of through-vias 140 may be smaller than a maximum width of the first back pad 170A corresponding thereto.

The plurality of through-vias 140 may include a via plug 145 and a surface barrier layer 141 that surrounds a side surface of the via plug 145. The via plug 145 may include, for example, tungsten (W), titanium (Ti), aluminum (Al), or copper (Cu), and may be formed using a plating process, a PVD process, or a CVD process. The surface barrier layer 141 may include titanium (Ti), titanium nitride (TiN), tantalum (Ta), or tantalum nitride (TaN), and may be formed using a plating process, a PVD process, or a CVD process.

In addition, a side insulating film 147 that extends along some side surfaces of the plurality of through-vias 140 surrounded by the substrate 110 may be formed around the plurality of through-vias 140. The side insulating film 147 may electrically separate or isolate the via plug 145 from the substrate 110. The side insulating film 147 may include an insulating material (e.g., high aspect ratio process (HARP) oxide) such as silicon oxide, silicon nitride, or silicon oxynitride, and may be formed using a PVD process or a CVD process.

The back protective layer 150 may be on the back surface BS of the substrate 110, and may surround at least a portion of each of the through-vias 140 and the dummy patterns 160. The back protective layer 150 may include an insulating material, such as silicon oxide (SiO), silicon nitride (SiN), silicon carbide (SiC), silicon oxynitride (SiON), silicon carbonitride (SiCN), or the like. The back protective layer 150 may protect the back surface BS of the substrate 110, and may electrically insulate the dummy patterns 160 and the back pads 170 from the substrate 110. In some embodiments, the back protective layer 150 may include a plurality of protective layers. In some embodiments, the back protective layer 150 may include a first protective layer 151 and a second protective layer 152.

The first protective layer 151 may be between the substrate 110 and the first back pads 170A, and may surround a portion of a side surface of the through-via 140. A buffer film 151BP, such as a polishing stop layer or barrier, may be arranged above the first protective layer 151. The buffer film 151BP may include silicon nitride (SiN), silicon carbide (SiC), silicon oxynitride (SiON), silicon carbonitride (SiCN), or the like. FIG. 1D omits the buffer film 151BP and illustrates only the first protective layer 151 and the second protective layer 152. The through-vias 140 may penetrate or extend through the first protective layer 151 and may contact lower surfaces of the first back pads 170A corresponding thereto.

The second protective layer 152 may be between the dummy pattern 160 and the substrate 110, and may surround a side surface and lower surfaces of the dummy pattern 160. The second protective layer 152 may extend along an inner surface of the cavity RS in which the dummy pattern 160 is provided. A thickness 152T of the second protective layer 152 may be the same as or smaller than a thickness 151T of the first protective layer 151. The thickness 152T of the second protective layer 152 may range from about 1 μm to about 2 μm, but the present inventive concept is not limited thereto.

The plurality of dummy patterns 160 may be provided around the through-vias 140 so that at least one surface of the plurality of dummy patterns 160 is exposed to the back surface BS of the substrate 110. The plurality of dummy patterns 160 may include a barrier layer 161 and a conductor layer 165. For example, the barrier layer 161 may include titanium (Ti) or titanium nitride (TiN), and the conductor layer 165 may include copper (Cu). The plurality of dummy patterns 160 may be spaced apart from the through-via 140 and arranged in the cavity RS recessed from the back surface BS toward the front surface FS. In some embodiments, the cavity RS may be formed to a depth penetrating the first protective layer 151. The one surface (e.g., uppermost surface) of each of the plurality of dummy patterns 160 exposed in the vertical direction D3 may be coplanar with the upper surfaces of the through-vias 140 and the upper surfaces of the dummy patterns 160. In addition, the one surface (e.g., upper surface) of each of the plurality of dummy patterns 160 may be coplanar with the uppermost surface of the first protective layer 151 and the uppermost surface of the second protective layer 152. By partially burying the plurality of dummy patterns 160 in the substrate 110, heat dissipation characteristics can be improved without affecting a vertical gap between the first semiconductor chip 100A and the second semiconductor chip 100B.

The plurality of dummy patterns 160 may be connected to at least some of the back pads 170. For example, the plurality of dummy patterns 160 may overlap two or more second back pads 170B arranged in at least one direction of the first direction D1 and the second direction D2. When viewed in a plan view, the plurality of second back pads 170B may be arranged in the first direction D1 and the second direction D2, and at least one of the plurality of dummy patterns 160 may overlap two or more second back pads 170B. The two or more second back pads 170B may be in direct contact with the one surface (e.g., upper surface) of at least one dummy pattern. The maximum width of the at least one dummy pattern 160 may be greater than the sum of the widths of the two or more second back pads 170B.

The plurality of dummy patterns 160 may provide a large thermally conductive region connected to the plurality of second back pads 170B, so that the heat dissipation characteristics of the semiconductor package 10A may be improved. A thickness 160T of the plurality of dummy patterns 160 may be determined by considering heat dissipation characteristics and warpage characteristics. For example, the thickness 160T of the plurality of dummy patterns 160 may range from about 5 μm to about 15 μm, from about 5 μm to about 10 μm, or from about 7 μm to about 10 μm. When the thickness 160T of the plurality of dummy patterns 160 is less than about 5 μm, the heat dissipation improvement effect may be insignificant. When the thickness 160T of the plurality of dummy patterns 160 exceeds about 15 am, warpage characteristics may deteriorate. However, the thickness 160T of the plurality of dummy patterns 160 is not limited to the above-mentioned numerical range, and the thickness 160T of the plurality of dummy patterns 160 may be formed to a level, similar to the sum of thicknesses of the interconnection structure 125 on the front surface FS of the substrate 110. In an example embodiment, the thickness 160T of the plurality of dummy patterns 160 may be greater than the thickness 151T of the first protective layer 151.

In some embodiments, at least some of the plurality of dummy patterns 160 may be formed to extend in the same direction as the top conductors TC of the interconnection structure 125 aligned in the vertical direction D3. For example, when viewed in a plan view, at least some of the connection conductors TC (‘first connection conductor TCa’) may be electrically connected to two or more second front pads 132B arranged in at least one direction of the first direction D1 and the second direction D2. In this case, two or more second back pads 170B respectively connected to the two or more second front pads 132B may be electrically connected to a first dummy pattern 160a, and the first dummy pattern 160a and the first connection conductor (TCa) may have a rectangular shape extending in the same direction (see FIGS. 1C and 1D). That is, the first dummy pattern 160a may extend in a direction that does not intersect the first connection conductor TCa, thereby preventing short circuits between adjacent first connection conductors TCa.

The plurality of dummy patterns 160 may be arranged in a region that is isolated from the through-vias 140. For example, the plurality of through-vias 140 may be arranged in the first region R1 that crosses a center of the semiconductor chip, and the plurality of dummy patterns 160 may be arranged in the second region R2 around or on first and second sides of the first region R1. For example, the first region R1 may be a region in which input/output circuits for a memory circuit (or memory block) are formed, and the second region R2 may be a region in which memory cells, word lines, and bit lines are formed. However, the shapes of the first region R1 and the second region R2 are not limited to those shown in the drawings, and may be variously designed.

The plurality of back pads 170 may be on the back surface BS of the substrate 110, and may be connected to the plurality of through-vias 140. The plurality of back pads 170 may be electrically connected to at least some of the plurality of front pads 132 through the plurality of through-vias 140 and the interconnection structure 125. The plurality of back pads 170 may be electrically connected to the plurality of front pads 170 adjacent to each other in the vertical direction D3. For example, the plurality of back pads 170 may be electrically connected to the front pads 132 of the second semiconductor chip 100B, which may be aligned in the vertical direction D3 of the back pads 170 of the first semiconductor chip 100A.

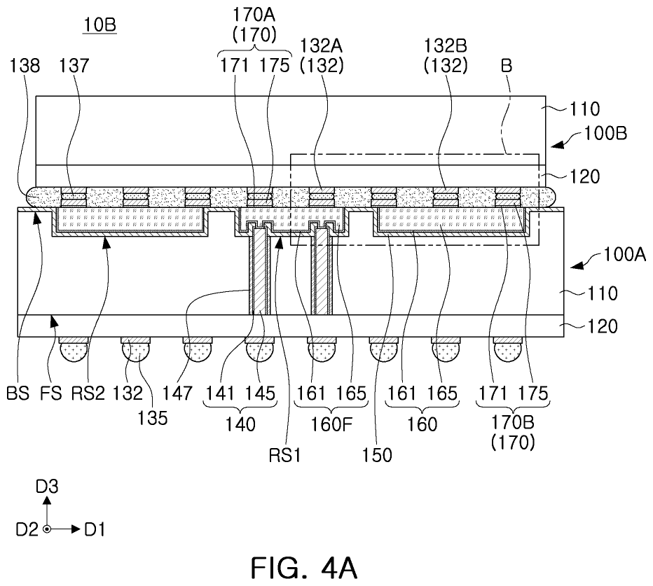

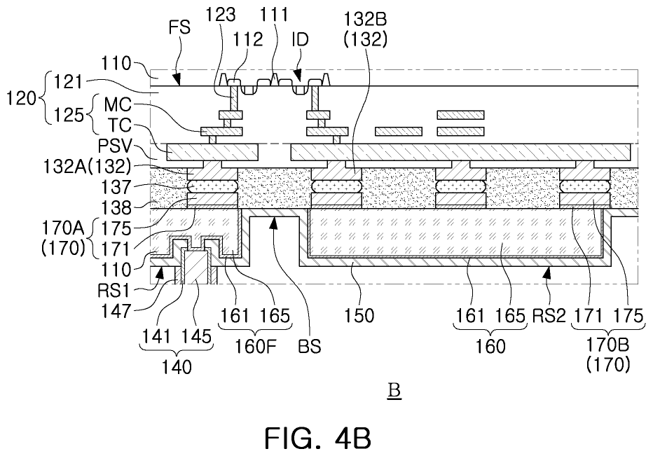

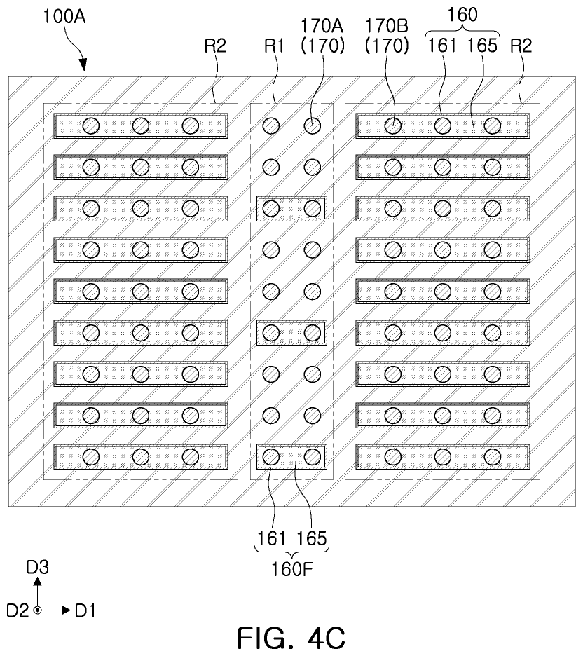

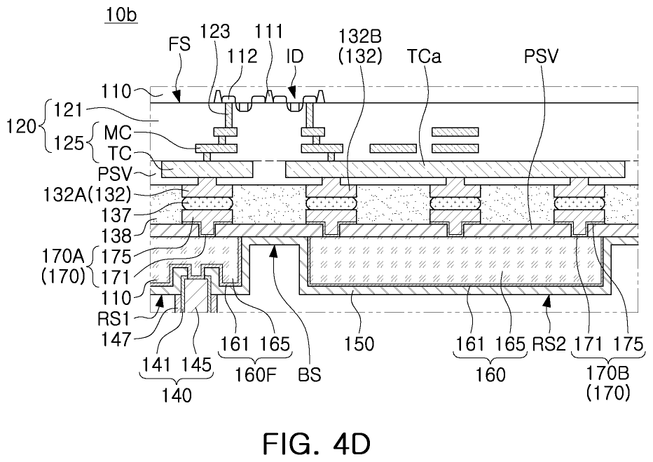

The plurality of back pads 170 may be on a plurality of through-vias 140 and a plurality of dummy patterns 160. In some embodiments, the plurality of back pads 170 may be arranged on a passivation layer that covers the plurality of through-vias 140 and the plurality of dummy patterns 160 (see the embodiment of FIG. 4C). The plurality of back pads 170 may include a barrier layer 171 and a conductor layer 175. The barrier layer 171 may include, for example, titanium (Ti), titanium nitride (TiN), tantalum (Ta), or tantalum nitride (TaN). The conductor layer 175 is, for example, aluminum (Al), gold (Au), cobalt (Co), copper (Cu), nickel (Ni), lead (Pb), tantalum (Ta), tellurium (Te), titanium (Ti), tungsten (W), or a combination of two or more thereof.

The plurality of back pads 170 may include a plurality of first back pads 170A and a plurality of second back pads 170B. The plurality of first back pads 170A may be respectively arranged on the through-vias 140. The plurality of first rear pads 170A may be connected to a signal wiring, a power wiring, and a ground wiring, of the interconnection structure 125 through the through-vias 140. The plurality of second back pads 170B may be arranged on the dummy patterns 160. The plurality of second back pads 170B may be connected to corresponding dummy patterns 160. The plurality of second back pads 170B may be understood as non-functional pads or dummy pads. The plurality of second back pads 170B may include a barrier layer 171 in contact with an upper surface of the corresponding dummy pattern 160, and a conductor layer 175 on the barrier layer 171.

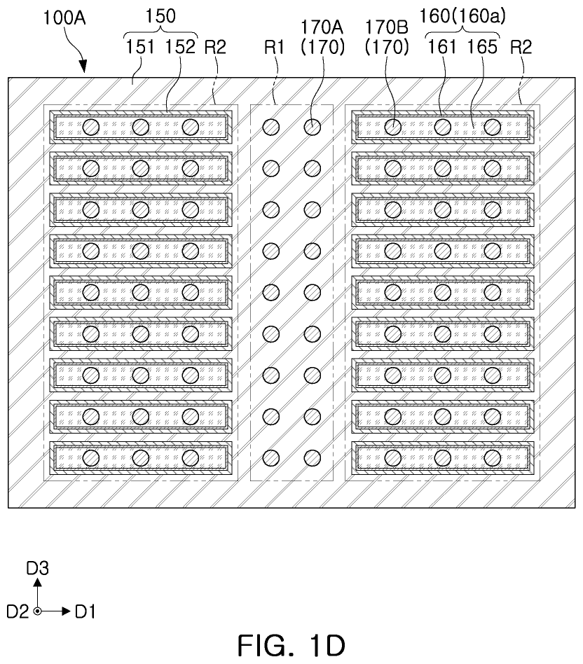

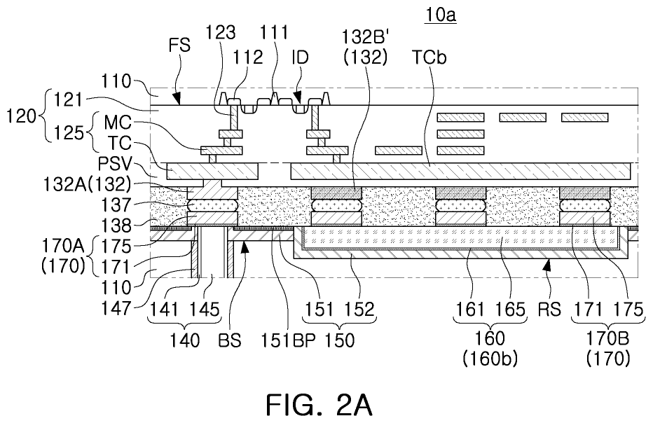

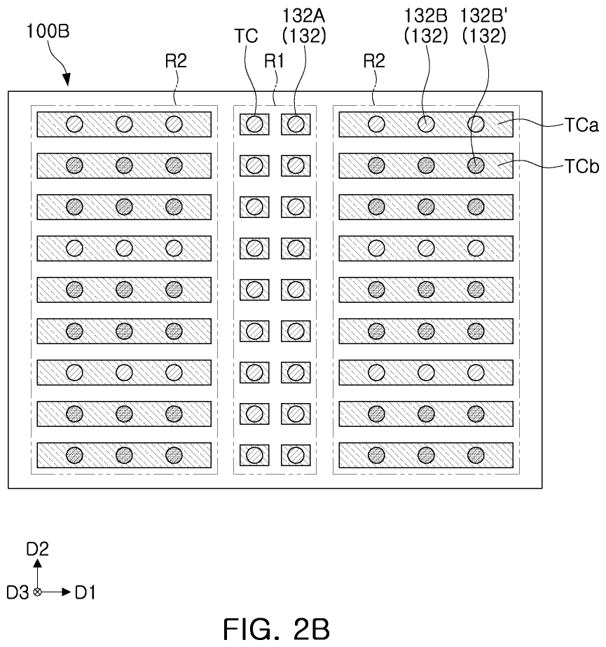

FIG. 2A is a partially enlarged view of a semiconductor package 10a according to some embodiments, FIG. 2B is a bottom view of the upper semiconductor chip of FIG. 2A, and FIG. 2C is a plan view of the lower semiconductor chip of FIG. 2A. FIG. 2A illustrates a partial region of the semiconductor package 10a corresponding to FIG. 1B.

Referring to FIGS. 2A to 2C, the semiconductor package 10a according to some embodiments may have the same or similar features as those described with reference to FIGS. 1A to 1D except that the semiconductor package 10a further includes at least a portion of dummy patterns 160b having a different shape from top conductors TC of the interconnection structure 125.

In some embodiments, at least some of the connection conductors TC (‘second connection conductor TCb’) may be electrically insulated from two or more second front pads 132B′ arranged in at least one direction of the first direction D1 and the second direction D2. In this case, two or more second back pads 170B, respectively connected to the two or more second front pads 132B′, may be electrically connected to a second dummy pattern 160b, and the second dummy pattern 160b and the second connection conductor TCb may have different planar shapes.

For example, the second connection conductor TCb may be formed in a polygonal shape with a planar area overlapping the second front pads 132B′ arranged in one row, and the second dummy pattern 160b may be formed in a polygonal shape with a planar area overlapping the second back pads 170B arranged in two or more rows. In some embodiments, the second connection conductor TCb may be a functional wiring, for example, a signal, power, or ground wiring, and the second front pads 132B′ electrically insulated from the second connection conductor TCb may be understood to be non-functional pads or dummy pads.

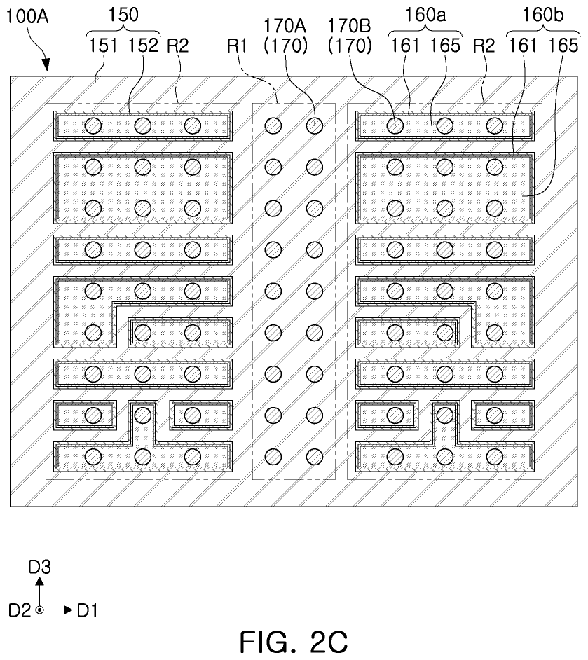

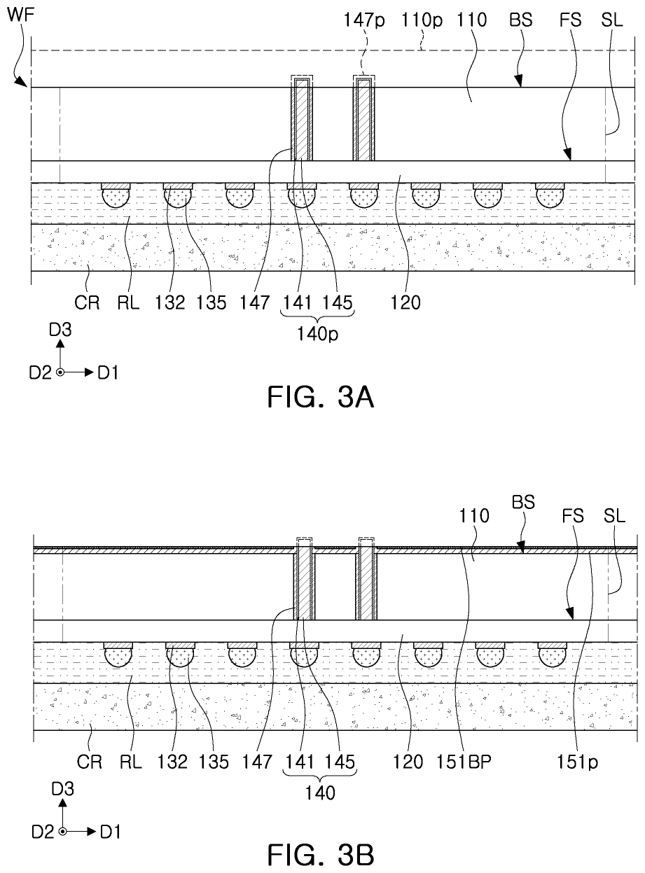

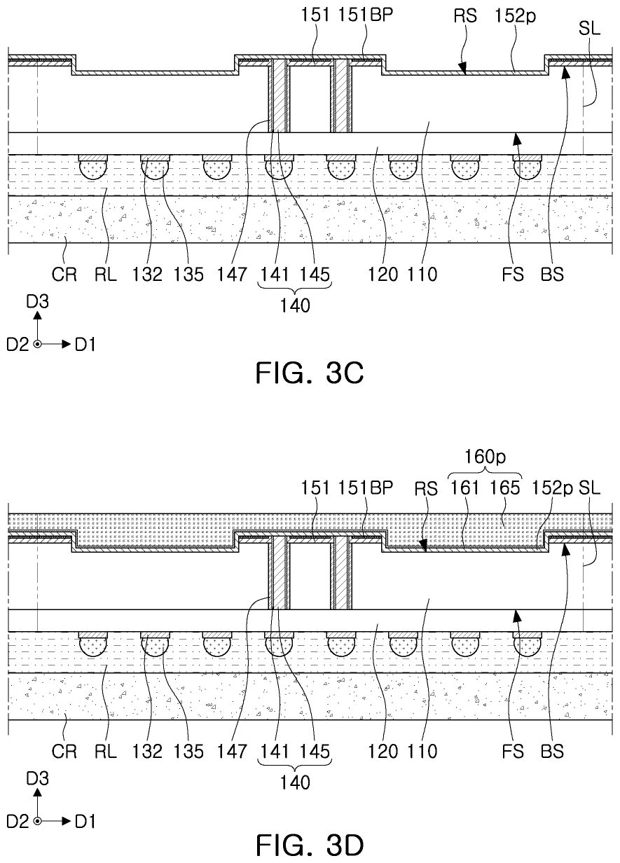

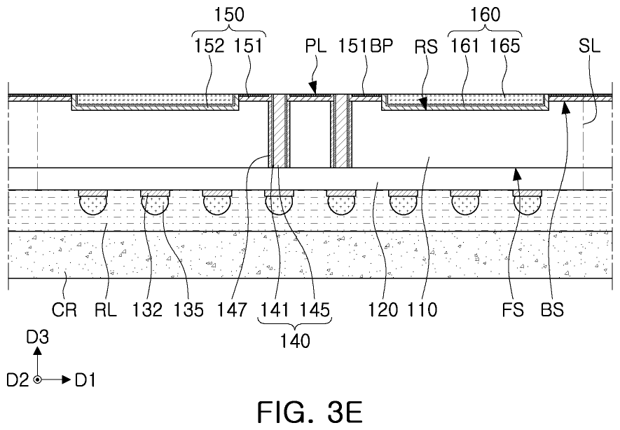

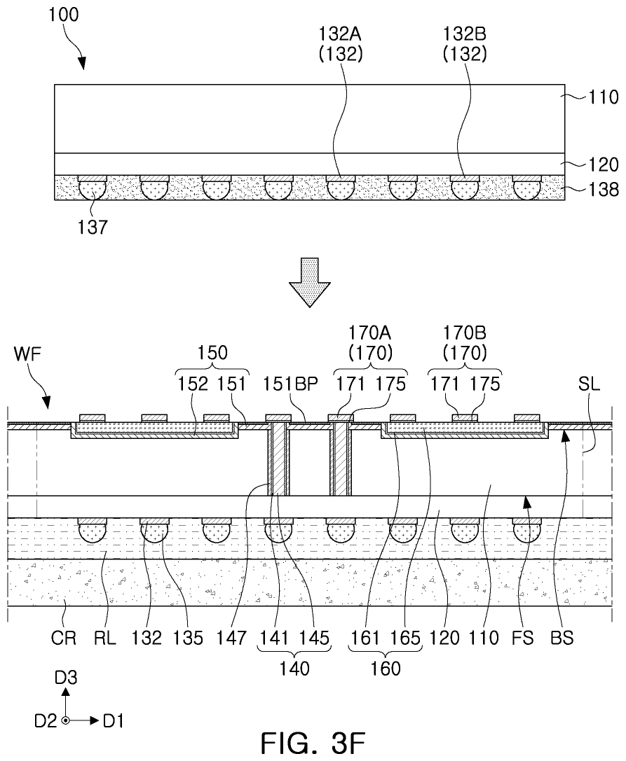

FIGS. 3A to 3F are diagrams for explaining a manufacturing method of the semiconductor package 10A of FIG. 1A.

Referring to FIG. 3A, a semiconductor wafer WF may be temporarily supported by a carrier wafer CR by a bonding material layer RL such as glue. The semiconductor wafer WF may include a plurality of chip regions divided by scribe lines SL. The semiconductor wafer WF may have a front circuit layer 120, front pads 132, and external connection bumps 135 formed on a front surface FS of a preliminary substrate 110p. The semiconductor wafer WF may include preliminary through-vias 140p that extend from the front surface FS of the preliminary substrate 110p. A preliminary side insulating film 147p may be between the preliminary through-vias 140p and the preliminary substrate 110p. The preliminary side insulating film 147p may include, for example, a HARP oxide layer.

By applying a polishing process to the preliminary substrate 110p, a substrate 110 may be formed, the substrate 110 having a back surface BS from which the preliminary through-vias 140p protrude. The polishing process may be a chemical mechanical polishing (CMP) process, an etch-back process, or a combination thereof. For example, the preliminary substrate 110p may be reduced to a certain thickness by performing a CMP process, and the preliminary through-vias 140p may be sufficiently exposed by applying etch-back under appropriate conditions. Using the polishing process, a portion of the preliminary substrate 110p and a portion of the preliminary side insulating film 147p may be removed.

Referring to FIG. 3B, a first preliminary protective layer 151p and a buffer film 151BP may be formed on the back surface BS of the substrate 110. The first preliminary protective layer 151p may be silicon oxide, and the buffer film 151BP may be silicon nitride or silicon oxynitride. The first preliminary protective layer 151p and the preliminary buffer layer 151BP may be formed using a PVD process or a CVD process. A planarization (e.g., grinding) process may be applied to the first preliminary protective layer 151p and the preliminary buffer film 151BP so that the through-vias 140 are exposed. Through the planarization process, a portion of each of the first preliminary protective layer 151p, the buffer film 151BP, and the preliminary through-vias 140p may be removed.

Referring to FIG. 3C, cavities RS extending into the semiconductor wafer WF may be formed. The cavities RS may be formed by etching a portion of the semiconductor wafer WF (or the substrate 110). As an etching process, for example, a reactive-ion etching (RIE) process may be used. The cavities RS may be formed to a depth penetrating the first preliminary protective layer 151p. Inner surfaces of the cavities RS may be defined by the substrate 110 and the first protective layer 151.

Subsequently, a second preliminary protective layer 152p may be formed covering the inner surfaces of the cavities RS. The second preliminary protective layer 152p may be silicon oxide and may be formed using a PVD process or CVD process. The second preliminary protective layer 152p may be formed to have the same or smaller thickness than the first protective layer 151. The second preliminary protective layer 152p may extend to the upper surfaces of the first protective layer 151 and the through-vias 140.

Referring to FIG. 3D, a preliminary pattern layer 160p including a barrier layer 161 and a conductor layer 165 may be formed on the second preliminary protective layer 152p. The barrier layer 161 may be formed along and may conform to a surface of the second preliminary protective layer 152p. The conductor layer 165 may be formed on the barrier layer 161, and may fill the interior of the cavities RS. The barrier layer 161 and the conductor layer 165 may be formed using a plating process, PVD process, or CVD process. For example, the conductor layer 165 may be formed using a plating process using the barrier layer 161 as a seed layer. The barrier layer 161 may include titanium (Ti) or titanium nitride (TiN), and the conductor layer 165 may include copper (Cu).

Referring to FIG. 3E, dummy patterns 160 with at least one side exposed may be formed. The dummy patterns 160 may be formed by applying a polishing process (e.g., CMP) to the second preliminary protective layer 152p, the barrier layer 161, and the conductor layer 165. Using the polishing process, a portion of the second preliminary protective layer 152p may be removed to form a second protective layer 152 that surrounds the lower surface and side surfaces of the dummy patterns 160. The upper surfaces of the dummy patterns 160, the upper surface of the first protective layer 151, the uppermost surface of the second protective layer 152, and the upper surfaces of the through-vias 140 may form the same planar surface PL.

Referring to FIG. 3F, a plurality of back pads 170 may be formed on the through-vias 140 and the dummy patterns 160. The plurality of back pads 170 may include a barrier layer 171 and a conductor layer 175. The barrier layer 171 and the conductor layer 175 may be formed using a plating process, PVD process, or CVD process. For example, the conductor layer 175 may be formed using a plating process using the barrier layer 171 as a seed layer. The barrier layer 171 may include titanium (Ti) or titanium nitride (TiN), and the conductor layer 175 may include copper (Cu). The plurality of back pads 170 may include first back pads 170A connected to the through-vias 140 and second back pads 170B connected to the dummy patterns 160.

Subsequently, the semiconductor chip 100 with the adhesive layer 138 attached may be arranged on the semiconductor wafer WF. The semiconductor chip 100 may be bonded to the semiconductor wafer WF through a thermal compression process. The semiconductor chip 100 may include a plurality of front pads 132 corresponding to the plurality of back pads 170.

FIG. 4A is a cross-sectional view of a semiconductor package 10B according to some embodiments, FIG. 4B is a partially enlarged view of area ‘B’ of FIG. 4A, FIG. 4C is a plan view of the lower semiconductor chip of FIG. 4A, and FIG. 4D is a diagram for explaining an example of a modification of a semiconductor package.

Referring to FIGS. 4A to 4C, the semiconductor package 10B according to some embodiments may have the same or similar characteristics as those described with reference to FIGS. 1A to 2C, except that the semiconductor package 10B may include at least one functional pattern 160F connected to two or more first back pads 170A. The at least one functional pattern 160F may include a barrier layer 161 and a conductor layer 165. For example, the barrier layer 161 may include titanium (Ti) or titanium nitride (TiN), and the conductor layer 165 may include copper (Cu). The at least one functional pattern 160F may include materials included in the dummy patterns 160, and may be formed during a same process as the dummy patterns 160.

At least one functional pattern 160F may be between the plurality of first back pads 170A and through-vias 140. The at least one functional pattern 160F may be electrically insulated from dummy patterns 160. For example, the at least one functional pattern 160F may interconnect two or more through vias 140 connected to a signal wiring, a power wiring, or a ground wiring, to improve electrical characteristics. When viewed in a plan view, at least one functional pattern 160F may overlap two or more first back pads 170A arranged in at least one of a first direction D1 and a second direction D2.

In some embodiments, the substrate 110 may have a first cavity RS1 in which at least one functional pattern 160F is provided, and second cavities RS2 in which dummy patterns 160 are provided. The back protective layer 150 may extend along the back surface BS of the substrate 110, and an inner surface of the first cavity RS1, and an inner surface of each of the second cavities RS2. The back protective layer 150 may surround side surfaces and lower surfaces of each of the at least one functional pattern 160F and the dummy patterns 160. The back protective layer 150 may have an opening OP that exposes at least a portion of the through-via 140 located within the first cavity RS1, and at least one functional pattern 160F may be electrically connected to the through-via 140 within the first cavity RS1 through the opening OP.

Referring to FIG. 4D, in a modified example, the semiconductor package 10b may further include a passivation layer PSV that covers at least one functional pattern 160F and the dummy patterns 160. The passivation layer PSV may include silicon oxide (SiO), silicon nitride (SiN), silicon carbide (SiC), silicon oxynitride (SiON), silicon carbonitride (SiCN), and the like. The plurality of back pads 170 may include via portions that penetrate the passivation layer PSV and that contact at least one functional pattern 160F and the dummy patterns 160, which correspond to each other, respectively.

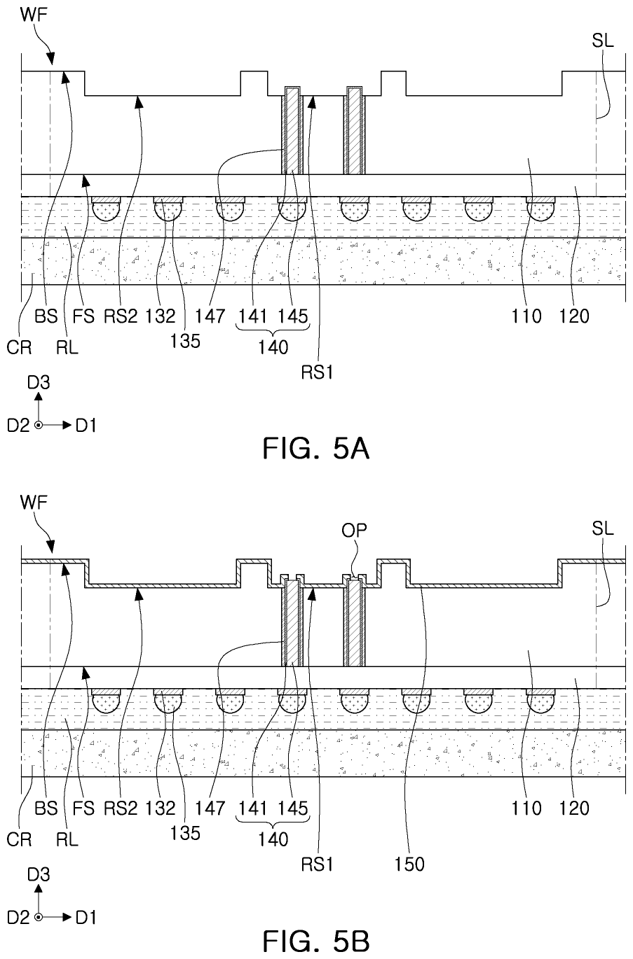

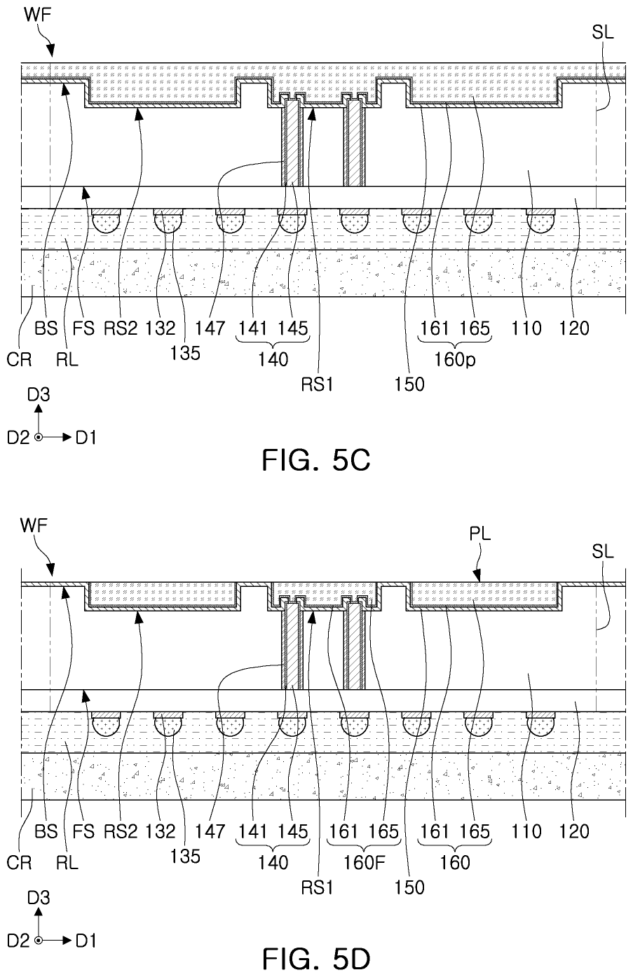

FIGS. 5A to 5D are diagrams for explaining a manufacturing method of the semiconductor package 10B of FIG. 4A.

Referring to FIG. 5A, a first cavity RS1 and a second cavity RS2 may be formed on a back surface BS of a semiconductor wafer WF (or a substrate 110). The first cavity RS1 and the second cavity RS2 may be formed by etching a portion of the substrate 110. As an etching process, for example, a reactive-ion etching (RIE) process may be used. The first cavity RS1 may be formed to a depth at which upper portions of the through-vias 140 protrude. The semiconductor wafer WF may be temporarily supported on a carrier wafer CR by a bonding material layer RL. The semiconductor wafer WF may include a plurality of chip regions divided by scribe lines SL. A thickness of the substrate 110 may be reduced by applying a polishing process to the back surface BS thereof, but the thickness of the substrate 110 may be greater than heights of the through-vias 140. During a process of forming the first cavity RS1, upper portions of the through-vias 140 may be exposed from a side insulating film 147.

Referring to FIG. 5B, a back protective layer 150 may be formed on the semiconductor wafer WF. The back protective layer 150 may include silicon oxide, silicon nitride, and the like. The back protective layer 150 may be formed using a PVD process or CVD process. The back protective layer 150 may extend along and may conform to surfaces (e.g., inner surfaces, side surfaces, or bottom surfaces) of the first cavity RS1 and the second cavity RS2. The back protective layer 150 may have openings OP that expose at least a portion of the through-vias 140 within the first cavity RS1. The openings OP may be formed using a photolithography process, an etching process, and the like. During a process of forming the openings OP, a portion of a surface barrier layer 141 may be removed together.

Referring to FIG. 5C, a preliminary pattern layer 160p including a barrier layer 161 and a conductor layer 165 may be formed on the back protective layer 150. The barrier layer 161 may be formed along and may conform to a surface of the back protective layer 150. The conductor layer 165 may be formed on the barrier layer 161, and may fill the interior of the first and second cavities RS1 and RS2. The barrier layer 161 and the conductor layer 165 may be formed using a plating process, PVD process, or CVD process. For example, the conductor layer 165 may be formed using a plating process using the barrier layer 161 as a seed layer. The barrier layer 161 may include titanium (Ti) or titanium nitride (TiN), and the conductor layer 165 may include copper (Cu).

Referring to FIG. 5D, a functional pattern 160F and dummy patterns 160 may be formed. The functional pattern 160F and the dummy patterns 160 may be formed by applying a polishing process (e.g., CMP) to the preliminary pattern layer 160p. Through the polishing process, the functional pattern 160F and the dummy patterns 160 respectively in the first cavity RS1 and the second cavity RS2 may be formed. An upper surface of the functional pattern 160F, upper surfaces of the dummy patterns 160, and an uppermost surface of the back protective layer 150 may form the same planar surface PL.

Subsequently, as described with reference to FIG. 3F, a plurality of back pads 170 may be formed, and a semiconductor chip may be attached to an upper portion of the semiconductor wafer WF. In the case of the modified example of FIG. 4D, a passivation layer PSV may be first formed on the functional pattern 160F and the dummy patterns 160.

FIG. 6 is a cross-sectional view of a semiconductor package 10C according to some embodiment.

Referring to FIG. 6, the semiconductor package 10C according to some embodiments may have the same or similar features as those described with reference to FIGS. 1A to 5D, except that a plurality of semiconductor chips 100A and 100B are directly bonded and coupled without a separate connection member (e.g., metal pillar, solder bump, adhesive film, and the like), which may be referred to as hybrid bonding, direct bonding, and the like.

The first semiconductor chip 100A may include a first passivation layer PSV1 surrounding a plurality of back pads 170. The second semiconductor chip 100B may include a second passivation layer PSV2 surrounding a plurality of front pads 132. The plurality of back pads 170 and the plurality of front pads 132 may include, for example, any one of copper (Cu), nickel (Ni), gold (Au), and silver (Ag) or alloys thereof. The first passivation layer PSV1 and the second passivation layer PSV2 may include a material that may be bonded and coupled to each other, for example, at least one of silicon oxide (SiO) and silicon carbonitride (SiCN). The first semiconductor chip 100A and the second semiconductor chip 100B may be bonded and coupled to each other by inter-metal bonding of the plurality of back pads 170 and the plurality of front pads 132 and inter-dielectric bonding of the first passivation layer PSV1 and the second passivation layer PSV2.

FIG. 7 is a cross-sectional view of a semiconductor package 10D according to some embodiments.

Referring to FIG. 7, the semiconductor package 10D according to some embodiments may have the same or similar features as those described with reference to FIGS. 1A to 6, except for including a chip structure CS and a molding member 180 on the first semiconductor chip 100A.

The chip structure CS may include a plurality of semiconductor chips, for example, a second semiconductor chip 100B, a third semiconductor chip 100C, a fourth semiconductor chip 100D, and a fifth semiconductor chip 100E. The first to fourth semiconductor chips 100A, 100B, 100C, and 100D may include dummy patterns 160 connected to the plurality of second back pads 170B. The fifth semiconductor chip 100E may not have dummy patterns 160.

Connection bumps 137 and adhesive layers 138 may be between each of the first to fifth semiconductor chips 100A, 100B, 100C, 100D, and 100E. The fifth semiconductor chip 100E that is an uppermost among the plurality of semiconductor chips may not have through-vias 140. In some embodiments, the chip structure CS may include more or fewer semiconductor chips than those shown in the drawing. For example, the chip structure CS may include three or less or five or more semiconductor chips.

For example, the first semiconductor chip 100A may be a buffer chip or control chip including a plurality of logic elements and/or memory elements. The first semiconductor chip 100A may transmit signals to an external destination (not shown) that are received from the second to fifth semiconductor chips 100B, 100C, 100D, and 100E stacked above the first semiconductor chip 100A. Additionally, the first semiconductor chip 100A may transmit signals and power from an external source (not shown) to the second to fifth semiconductor chips 100B, 100C, 100D, and 100E. The external destination and the external source may be the same device or may be different devices. The second to fifth semiconductor chips 100B, 100C, 100D, and 100E may be memory chips including volatile memory devices such as DRAM and SRAM, or non-volatile memory devices such as PRAM, MRAM, FeRAM, or RRAM. In some embodiments, the semiconductor package 10D may be used in high bandwidth memory (HBM) products, electro data processing (EDP) products, or the like.

The molding member 180 may be on the first semiconductor chip 100A, and may seal at least a portion of each of the second to fifth semiconductor chips 100B, 100C, 100D, and 100E. As seen in FIG. 7, the molding member 180 may be formed such that an upper surface of the fifth semiconductor chip 100E is exposed. However, in some embodiments, the molding member 180 may be formed to cover the upper surface of the fifth semiconductor chip 100E. The molding member 180 may include, for example, epoxy mold compound (EMC), but a material of the molding member 180 is not particularly limited.

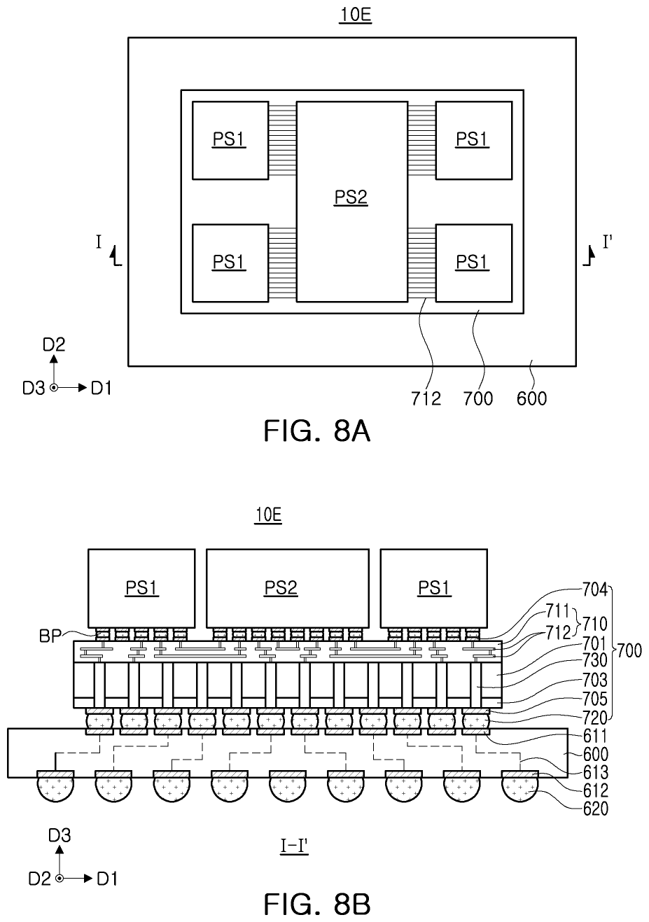

FIG. 8A is a plan view of a semiconductor package 10E according to some embodiments, and FIG. 8B is a cross-sectional view taken along line I-I′ of FIG. 8A.

Referring to FIGS. 8A and 8B, the semiconductor package 10E according to some embodiments may include a package substrate 600, an interposer substrate 700, and at least one package structure PS1 and PS2. The package structures PS1 and/or PS2 may be provided in more or fewer numbers than shown in the drawing.

The at least one package structures PS1 and PS2 may include a first package structure PS1 and a second package structure PS2 that are connected to each other through the interposer substrate 700. At least one of the first package structure PS1 and the second package structure PS2 may be understood as a semiconductor package having the characteristics described with reference to FIGS. 1A to 7. The first package structure PS1 and the second package structure PS2 may be connected to the interposer substrate 700 through conductive bumps BP. The second package structure PS2 may include a different type of semiconductor chip from the first package structure PS1. For example, the first package structure PS1 may include a logic chip, and the second package structure PS2 may include a memory chip, with the understanding that the present disclosure is not limited thereto.

The package substrate 600 may be a support substrate on which the interposer substrate 700 is mounted, and may be a substrate for a semiconductor package including a printed circuit board (PCB), a ceramic substrate, a glass substrate, a tape wiring substrate, or the like. The package substrate 600 may include a lower pad 612, an upper pad 611, and a wiring circuit 613. An external connection bump 620 connected to the lower pad 612 may be on a lower surface of the package substrate 600. The external connection bump 620 may include, for example, a solder ball.

The interposer substrate 700 may include a substrate 701, a lower protective layer 703, a lower terminal 705, an interconnection structure 710, a conductive bump 720, and a through-via 730. The first package structure PS1 and the second package structure PS2 may be electrically connected to each other via the interposer substrate 700.

The substrate 701 may be formed of, for example, any one of silicon, organic, plastic, and glass substrates. When the substrate 701 is a silicon substrate, the interposer substrate 700 may be referred to as a silicon interposer. In some embodiments, and in contrast to what is shown in the drawing, when the substrate 701 is an organic substrate, the interposer substrate 700 may be referred to as a panel interposer.

The lower terminal 705 may be connected to the through-via 730. The lower terminal 705 may be electrically connected to the package substrate 600 through conductive bumps 720.

The interconnection structure 710 may be on an upper surface of the substrate 701, and may include an interlayer insulating layer 711 and a single-layer or multilayer interconnection structure 712. When the interconnection structure 710 is formed of a multilayer interconnection structure, wiring patterns of different layers may be connected to each other through contact-vias. An upper terminal 704 connected to the interconnection structure 712 may be on the interconnection structure 710.

The through-via 730 may extend from the upper surface to the lower surface of the substrate 701 and may penetrate or extend through the substrate 701. For example, the through-via 730 may extend into the interior of the interconnection structure 710, and be electrically connected to wires of the interconnection structure 710. When the substrate 701 is silicon, the through-via 730 may be referred to as a TSV.

As set forth above, according to example embodiments, a semiconductor package having improved heat dissipation characteristics may be provided by introducing a dummy pattern connected to a plurality of pads on a back surface of a semiconductor chip.

The various and beneficial advantages and effects of the present inventive concept are not limited to those described above, and may be more easily understood through description of specific embodiments of the present inventive concepts.

While some examples of embodiments have been illustrated and described above, it will be apparent to those skilled in the art that modifications and variations could be made without departing from the scope of the present inventive concepts as defined by the appended claims.

What is claimed is:

1. A semiconductor package comprising:
a first semiconductor chip including:
a substrate having a front surface and a back surface, opposing each other,
through-vias that extend from the front surface toward the back surface,
dummy patterns arranged around the through-vias and such that at least one surface of each of the dummy patterns is exposed to the back surface,
a plurality of first back pads arranged on the through-vias, and
a plurality of second back pads arranged on a first surface of the at least one surface of each of the dummy patterns exposed to the back surface; and
a second semiconductor chip on the first semiconductor chip, and including a plurality of first front pads connected to the plurality of first back pads, and a plurality of second front pads connected to each of the plurality of second back pads,
wherein, when viewed in a plan view, the plurality of second back pads are arranged in a first direction and a second direction, perpendicular to the first direction, and
wherein when viewed in the plan view, at least one of the dummy patterns overlaps two or more second back pads arranged in at least one direction of the first direction and the second direction among the plurality of second back pads.

2. The semiconductor package of claim 1, wherein the two or more second back pads are in direct contact with the first surface of at least one dummy pattern.

3. The semiconductor package of claim 1, wherein the first semiconductor chip further comprises a back protective layer on the back surface of the substrate, and surrounding at least a portion of each of the through-vias and the dummy patterns,
wherein the back protective layer includes a first protective layer between the substrate and the plurality of first back pads and a second protective layer between the substrate and the dummy patterns.

4. The semiconductor package of claim 3, wherein the through-vias penetrate the first protective layer and respectively contact the plurality of first back pads.

5. The semiconductor package of claim 3, wherein the first surface of each of the dummy patterns is coplanar with an upper surface of the first protective layer and an uppermost surface of the second protective layer.

6. The semiconductor package of claim 3, wherein a thickness of the second protective layer is equal to or less than a thickness of the first protective layer.

7. The semiconductor package of claim 6, wherein the thickness of the second protective layer is in a range of 1 μm to 2 μm.

8. The semiconductor package of claim 3, wherein a thickness of each of the dummy patterns is greater than the thickness of the first protective layer.

9. The semiconductor package of claim 8, wherein the thickness of each of the dummy patterns is in a range of 5 μm to 15 μm.

10. The semiconductor package of claim 1, wherein the first semiconductor chip further comprises at least one functional pattern between the plurality of first back pads and the through-vias, and a back protective layer surrounding at least a portion of each of the at least one functional pattern and the dummy patterns,
wherein the substrate has a first cavity in which the at least one functional pattern is provided, and second cavities in which the dummy patterns are provided, and
the back protective layer extends along the back surface of the substrate, an inner surface of the first cavity, and an inner surface of each of the second cavities.

11. The semiconductor package of claim 10, wherein the back protective layer has an opening that exposes at least a portion of through-vias located within the first cavity, and
wherein the at least one functional pattern is electrically connected to the through-via within the first cavity through the opening.

12. The semiconductor package of claim 10, wherein, when viewed in the plan view, the at least one functional pattern overlaps two or more first back pads arranged in at least one direction of the first direction and the second direction among the plurality of first back pads.

13. The semiconductor package of claim 1, wherein the second semiconductor chip further comprises an interconnection structure that is electrically connected to the plurality of first front pads,
wherein the interconnection structure includes connection conductors adjacent to the plurality of second front pads,
wherein when viewed in the plan view, the plurality of second front pads are arranged in the first direction and the second direction, and
wherein when viewed in the plan view, at least some of the connection conductors overlap two or more second front pads arranged in at least one direction of the first direction and the second direction among the plurality of second front pads.

14. The semiconductor package of claim 13, wherein the two or more second front pads are electrically connected to an overlapping first connection conductor among the connection conductors,
wherein the two or more second back pads respectively connected to the two or more second front pads are electrically connected to a first dummy pattern of the plurality of dummy patterns, and
wherein when viewed in the plan view, the first dummy pattern and the first connection conductor have a rectangular shape extending in the same direction.

15. The semiconductor package of claim 13, wherein the two or more second front pads are electrically insulated from an overlapping second connection conductor among the connection conductors,
wherein the two or more second back pads respectively connected to the two or more second front pads are electrically connected to a second dummy pattern of the plurality of dummy patterns, and
wherein when viewed in the plan view, the second dummy pattern and the second connection conductor have different shapes.

16. The semiconductor package of claim 1, further comprising:
a plurality of connection bumps electrically connecting the plurality of first front pads and the plurality of first back pads that correspond to each other, and electrically connecting the plurality of second front pads and the plurality of second back pads that correspond to each other; and
an adhesive layer between the first semiconductor chip and the second semiconductor chip, the adhesive layer covering at least a portion of each of the plurality of connection bumps.

17. A semiconductor package, comprising:
a first semiconductor chip including:
a substrate having a front surface and a back surface that oppose each other,
a through-via that extends from the front surface toward the back surface,
a dummy pattern spaced apart from the through-via and within a cavity that is recessed from the back surface toward the front surface,
a back protective layer between the substrate and the dummy pattern,
a first back pad on the through-via, and
a plurality of second back pads disposed on the dummy pattern; and
a second semiconductor chip on the first semiconductor chip, and including a first front pad connected to the first back pad, and a plurality of second front pads connected to each of the plurality of second back pads,
wherein the first back pad includes a first barrier layer that is in contact with an upper surface of the through-via, and a first conductor layer on the first barrier layer,
wherein a maximum width of the through-via in a horizontal direction is less than a maximum width of the first back pad in the horizontal direction,
wherein each of the plurality of second back pads includes a second barrier layer in contact with an upper surface of the dummy pattern, and a second conductor layer on the second barrier layer, and
wherein a width of the dummy pattern in the horizontal direction is greater than a sum of widths of each of the plurality of second back pads in the horizontal direction.

18. The semiconductor package of claim 17, wherein a upper surface of the through-via and the upper surface of the dummy pattern are coplanar.

19. The semiconductor package of claim 17, wherein the back protective layer comprises at least one of silicon oxide and silicon nitride.

20. A semiconductor package comprising:
a first semiconductor chip including:
a substrate having a front surface and a back surface that oppose each other,
a through-via that extends from the front surface toward the back surface,
a first back pad on the through-via,
a first protective layer between the substrate and the first back pad, and surrounding at least a portion of the through-via,
a dummy pattern within a cavity that penetrates the first protective layer,
a second protective layer between an inner surface of the cavity and the dummy pattern, and
a plurality of second back pads on the dummy pattern;
a second semiconductor chip on the first semiconductor chip, and including:
a first front pad connected to the first back pad, and
a plurality of second front pads respectively connected to the plurality of second back pads;
a plurality of connection bumps electrically connecting the first back pad and the first front pad, and the plurality of second back pads and the plurality of second front pads; and
an adhesive layer between the first semiconductor chip and the second semiconductor chip, and covering at least a portion of each of the plurality of connection bumps.
